(19) United States
(12) Patent Application Publication
(10) Pub. No.: US 2020/0279753 A1
(43) Pub. Date: Sep. 3, 2020

(54) SUBSTRATE PROCESSING METHOD AND SUBSTRATE PROCESSING APPARATUS

(71) Applicant: TOKYO ELECTRON LIMITED, Tokyo (JP)

(72) Inventors: Tomohiko NIIZEKI, Miyagi (JP); Yoshihide KIHARA, Miyagi (JP)

(73) Assignee: TOKYO ELECTRON LIMITED, Tokyo (JP)

(21) Appl. No.: 16/804,939

(22) Filed: Feb. 28, 2020

(30) Foreign Application Priority Data
Mar. 1, 2019 (JP) 2019-037737

(51) Int. Cl. H01L 21/3213; H01J 37/18; H01L 21/311; H01J 37/32; H01L 21/3065

(52) U.S. Cl. CPC H01L 21/32137; H01J 37/185; H01L 21/31144; H01J 2237/3151; H01L 21/3065; H01J 2237/006; H01J 37/32082

(57) ABSTRACT

A substrate processing method includes etching a target film formed on a substrate through an opening of a mask formed on the target film with plasma generated from a mixed gas obtained by adding a gas having a carbonyl bond to a halogen-containing gas. The target film contains silicon and the mask is formed of a transition metal.

### CROSS-REFERENCE TO RELATED APPLICATIONS

This application is based on and claims priority from Japanese Patent Application No. 2019-037737, filed on Mar. 1, 2019 with the Japan Patent Office, the disclosure of which is incorporated herein in its entirety by reference.

### TECHNICAL FIELD

The present disclosure relates to a substrate processing method and a substrate processing apparatus.

### BACKGROUND

Japanese Patent Laid-Open Publication No. 2016-207840 proposes a method of generating plasma from a hydrogen-containing gas and a fluorine-containing gas by radio-frequency power for plasma generation, and etching an etching target film of a silicon oxide film and a silicon nitride film with the generated plasma in an extremely low-temperature environment of −30° C. or lower. With this method, a high etching rate and a high selectivity are realized.

Japanese Patent Laid-Open Publication No. 2015-041624 proposes a method of reducing bowing of a shape obtained by exposing a workpiece having a silicon oxide film and a mask provided on the silicon oxide film to plasma of a processing gas so as to etch the silicon oxide film. In Japanese Patent Laid-Open Publication No. 2015-041624, the mask includes a film containing a metal.

### SUMMARY

According to an aspect of the present disclosure, there is provided a substrate processing method for processing a substrate including a mask formed of a transition metal and having an opening, and a silicon-containing etching target film formed below the mask. The substrate processing method including a step of etching the etching target film through the opening in the mask with plasma generated from a mixed gas obtained by adding a gas having a carbonyl bond to a halogen-containing gas.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an exemplary substrate processing apparatus according to an embodiment.

FIGS. 2A and 2B are views illustrating an exemplary etching shape.

FIGS. 3A to 3C are views illustrating exemplary results obtained by adding CO gas according to an embodiment.

FIGS. 4A to 4C are views comparing the presence/absence of addition of CO gas and shift amounts of etching.

FIG. 5 is a graph representing exemplary results of adding various gases during a treatment step according to an embodiment.

FIG. 6 is a graph representing a vapor pressure curve of a carbon monoxide complex of tungsten.

FIG. 7 is a flowchart illustrating an exemplary substrate processing method according to an embodiment.

### DESCRIPTION OF EMBODIMENT

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, embodiments of the present disclosure will be described with reference to the accompanying drawings. In each of the drawings, the same components are denoted by the same reference numerals, and redundant descriptions may be omitted.

[Substrate Processing Apparatus]

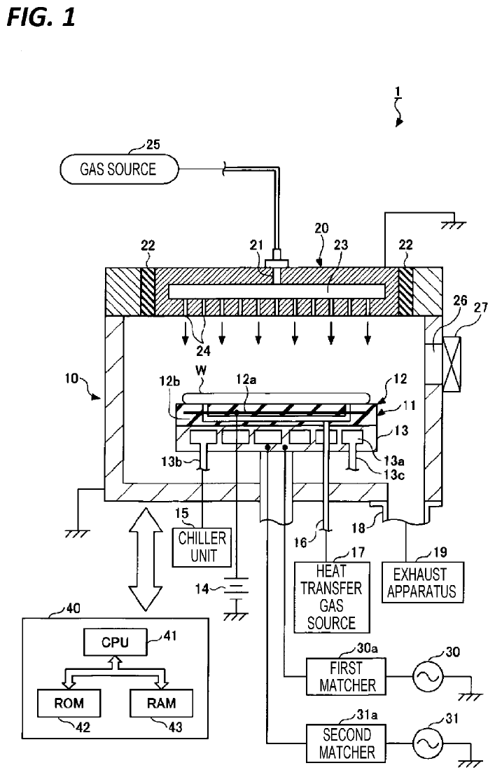

A substrate processing apparatus 1 according to an embodiment will be described with reference to FIG. 1. FIG. 1 is a schematic cross-sectional view illustrating an exemplary substrate processing apparatus 1 according to an embodiment. The plasma processing apparatus 1 according to an embodiment is a parallel flat plate type plasma processing apparatus in which a stage 11 and a gas shower head 20 are disposed to face each other inside a processing container 10.

The stage 11 has a function of holding a wafer W and functions as a lower electrode. The shower head 20 has a function of supplying a gas into the processing container 10 in the form of a shower and functions as an upper electrode.

The processing container 10 includes aluminum subjected to an alumite treatment (anodized) and has a cylindrical shape. The processing container 10 is electrically grounded. The stage 11 is installed on the bottom portion of the processing container 10, and a wafer W is placed thereon.

The stage 11 is made of, for example, aluminum (Al), titanium (Ti), or silicon carbide (SiC). The stage 11 includes an electrostatic chuck 12 and a base 13. The electrostatic chuck 12 is provided on the base 13. The electrostatic chuck 12 has a structure in which a chuck electrode 12a is sandwiched between insulators 12b. A power supply 14 is connected to the chuck electrode 12a. The electrostatic chuck 12 attracts the wafer W thereto by a Coulomb force generated by supplying current from the power supply 14 to the chuck electrode 12a.

The base 13 supports the electrostatic chuck 12. Inside the base 13, a coolant flow path 13a is formed. A coolant inlet pipe 13b and a coolant outlet pipe 13c are connected to the coolant flow path 13a. A cooling medium (heat medium) having a predetermined temperature is output from a chiller unit 15, and the cooling medium circulates through the coolant inlet pipe 13b, the coolant flow path 13a, and the coolant outlet pipe 13c. Thus, the stage 11 is cooled, and the wafer W is controlled to a predetermined temperature.

A heat transfer gas source 17 supplies a heat transfer gas such as, for example, helium gas through a gas supply line 16 to a gap between the surface of the electrostatic chuck 12 and the rear surface of the wafer W. Thus, the heat transfer efficiency between the electrostatic chuck 12 and the wafer W is increased, and the temperature controllability of the wafer W is improved.

The stage 11 includes a first radio-frequency power supply 30 for supplying radio-frequency power for plasma generation (hereinafter, also referred to as “HF power”) having a first frequency to the stage 11, and a second radio-frequency power supply 31 for ion attraction (hereinafter, also referred to as “LF power”) having a second frequency lower than the first frequency. The first radio-frequency power supply 30 is electrically connected to the stage 11 via a first matcher 30a. The second radio-frequency power supply 31 is electrically connected to the stage 11 via a second matcher 31a. The first radio-frequency power supply 30 applies radio-frequency power for plasma generation having a frequency of, for example, 40 MHz to the stage 11. The second radio-frequency power supply 31 applies radio-frequency power for ion attraction having a frequency of, for example, 400 kHz to the stage 11. Meanwhile, the first radio-frequency power supply 30 may apply the radio-frequency power for plasma generation to the shower head 20 instead of applying the radio-frequency power for plasma generation to the stage 11.

The first matcher 30a matches a load impedance of the stage 11 side with the output (internal) impedance of the first radio-frequency power supply 30. The second matcher 31a matches a load impedance of the stage 11 side with the output (internal) impedance of the second radio-frequency power supply 31.

The shower head 20 closes the opening of the ceiling portion of the processing container 10 via an insulator shield ring 22 covering the peripheral edge thereof. A gas introduction port 21 for introducing a gas is formed in the shower head 20. A diffusion chamber 23 connected to the gas introduction port 21 is formed inside the shower head 20. A processing gas output from a gas source 25 is supplied to the diffusion chamber 23 through the gas introduction port 21 and introduced from a large number of gas supply holes 24 to the inside of the processing container 10.

An exhaust port 18 is provided in the bottom portion of the processing container 10, and an exhaust apparatus 19 is connected to the exhaust port 18. The exhaust apparatus 19 evacuates the inside of the processing container 10. Thus, the inside of the processing container 10 is controlled to a predetermined degree of vacuum. A gate valve 27 is provided on the side wall of the processing container 10 to open/close a transfer port 26. As the gate valve 27 is opened/closed, a wafer W is loaded into the processing container 10 from the transfer port 26, or a wafer W is unloaded to the outside of the processing container 10.

The plasma processing apparatus 1 is provided with a controller 40 configured to control the operations of the entire apparatus. The controller 40 has a CPU 41, a ROM 42, and a RAM 43. The CPU 41 executes a cooling step, a treatment step, and an etching step of a wafer W according to various recipes stored in the storage areas of the ROM 42 and the RAM 43. The recipes include, for example, a process time, a pressure (gas exhaust), radio-frequency power and voltage, various gas flow rates, a temperature inside the processing container (an electrostatic chuck temperature), and a temperature of a cooling medium supplied from the chiller unit 15. Meanwhile, the recipes representing these programs and processing conditions may be stored in a hard disc or semiconductor memory. In addition, the recipes may be set at a predetermined position in a storage area in the state of being stored in a portable computer-readable storage medium such as, for example, a CD-ROM or a DVD.

When a substrate processing is performed, the opening/closing of the gate valve 27 is controlled, a wafer W is loaded into the processing container 10 from the transfer port 26 by a transfer arm (not illustrated), placed on the stage 11, and attracted to the electrostatic chuck 12.

Next, a processing gas is supplied from the shower head 20 into the processing chamber 10, and HF power for plasma generation is applied to the stage 11 so as to generate plasma. A treatment processing and an etching processing are performed on the wafer W by the generated plasma. In the etching processing, the LF power for ion attraction may be applied to the stage 11 together with HF power.

After the processings, the charge on the wafer W is removed by a charge removal processing, the wafer W is separated from the electrostatic chuck 12, the wafer W is held by a transfer arm (not illustrated), the gate valve 27 is opened, and the wafer W is unloaded out of the processing container 10.

[Necking Based on Residue of Mask of Transition Metal]

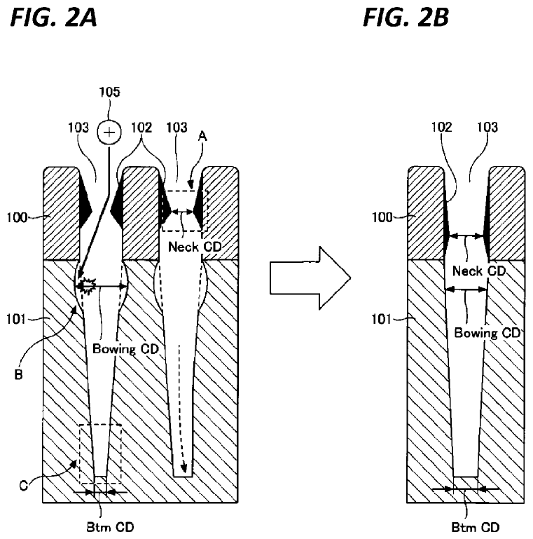

Necking in a substrate processing method, in which a wafer W having a mask formed of a transition metal and having an opening and an etching target silicon-containing film formed below the mask is transferred into a processing container 10 and processed, will be described. In the following, as illustrated in FIGS. 2A and 2B, a tungsten mask 100 is used as a transition metal mask, and a silicon oxide film 101 is used as an etching target film. Meanwhile, the shape of an opening 103 in the mask and the etching shape of the silicon oxide film 101 may have a hole shape or a line shape.

In the method of etching the silicon oxide film 101 using the tungsten mask 100, for example, in the state in which the temperature of the stage 11 is controlled to, for example, about −70° C. or lower, it is possible to considerably increase an etching rate.

However, in this method, tungsten residue 102 generated during the etching adheres to the mask 100 again. This causes so-called necking by which an opening 103 in the mask 100 is narrowed, the dimension of an opening 103 is changed, or an opening 103 is closed, as indicated by “A” in FIG. 2A. Hereinafter, the minimum width of an opening 103 in the mask 100 is referred to as a “neck CD.”

The necking causes the following problems (a) to (d) in a derivative manner.

(a) Due to the necking, ions 105 in plasma is not radiated vertically to the opening 103 in the mask 100, but is radiated obliquely to the opening 103. For this reason, the ions 105 collide with the side walls of the etched silicon oxide film 101, and the side walls are shaved, resulting in bowing indicated by “B” in FIG. 2A. The bowing refers to a phenomenon in which barrel-shaped thickening occurs in a relatively shallow portion in etching of a deep hole or the like. Hereinafter, the maximum width of the side wall of the silicon oxide film 101 will be referred to as a “bowing CD.”

(b) The narrowing of the opening 103 in the mask 100 makes it difficult for the ions 105 to enter the concave portion in the silicon oxide film 101, and thus the etching rate of the silicon oxide film 101 decreases.

(c) As indicated by “C” in FIG. 2A, the etching shape of the silicon oxide film 101 is tapered toward the tip, and the CD at the bottom of each concave portion formed in the silicon oxide film 101 (hereinafter, referred to as a “bottom CD”) is reduced.

(d) The vertical incidence of the ions 105 on each concave portion formed in the silicon oxide film 101 is hindered, and the etching shape of the silicon oxide film 101 is not vertical, but is bent (bending). When an opening 103 is a perfect circle, the hole shape of the silicon oxide film 101 is not a perfect circle, but is deformed into a shape such as, for example, an ellipse or a triangle (distortion). The bending refers to a phenomenon in which the shape of a deep hole or the like is not linear, but is bent in one direction or randomly.

Therefore, in the substrate processing method according to the present embodiment, the treatment and etching of the silicon oxide film 101 are simultaneously performed in the same step using the transition metal mask 100 in the state in which the stage 11 is controlled to have a predetermined temperature. At this time, the wafer W is treated with plasma generated by a gas having a carbonyl bond, and the wafer W is etched with plasma generated by a halogen-containing gas. This makes it possible to suppress necking so as to increase the neck CD, as shown in FIG. 2B. As a result, it is possible to form the etching shape of the silicon oxide film 101 vertically. This makes it possible to suppress the occurrence of bowing (increase of the bowing CD) and the tip tapering-off of the etching shape (decrease of the bottom CD).

[Test Result]

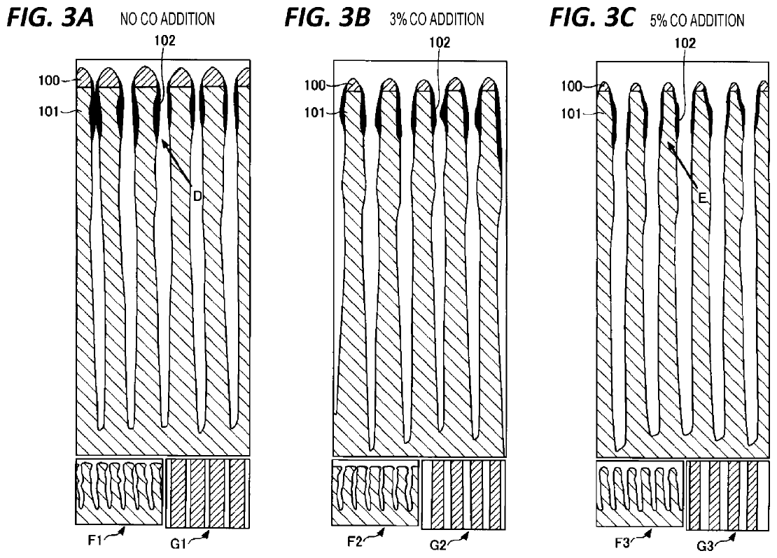

Next, test results obtained when CO gas was added to the processing gas will be described in comparison with test results obtained when CO gas was not added. FIGS. 3A to 3C are views illustrating exemplary test results obtained when a treatment step and an etching step were simultaneously performed in the same step using a processing gas to which CO gas is added according to one embodiment in comparison with test results when CO gas was not added.

In the following test, a line pattern was used as the pattern of openings 103 in the mask 100. The process conditions of this test are as follows.

<Process Condition: Treatment Step and Etching Step being Performed Simultaneously>

Gas species: H₂/CF₄/CO

Stage temperature: −30° C. to 0° C.

Pressure in processing container: 10 mT (13.3 Pa) to 100 mT (133.3 Pa)

HF power: On

LF power: On

Meanwhile, the treatment step and the etching step may be performed in different steps. In the case of being performed in different steps, the etching step is performed after the treatment step is performed. The process conditions in this case are as follows.

<Process Condition: Etching Step being Performed after Treatment Step>

(Treatment Step)

Gas species: CO

Stage temperature: −30° C. to 0° C.

Pressure in processing container: 10 mT (13.3 Pa) to 100 mT (133.3 Pa)

HF power: On

LF power: On

(Etching Step)

Gas species: Si₄H₂

Stage temperature: −30° C. to 0° C.

Pressure in processing container: 10 mT (1.33 Pa) to 100 mT (13.33 Pa)

HF power: On

LF power: On

The upper drawing of FIG. 3A is a cross-sectional view of an etching shape obtained by etching the silicon oxide film 101 without adding CO gas to the processing gas (H₂/CF₄) as a comparative example. According to this, since the amount of tungsten residue 102 re-adhering to the openings of concave portions formed in the mask 100 or the silicon oxide film 101 is large, necking occurs as indicated by “D” in FIG. 3A. F1 of the lower drawing (left) in FIG. 3A is a view obtained by vertically reducing the upper drawing of FIG. 3A, and G1 of the lower drawing (right) in FIG. 3A illustrates a view obtained by observing the mask 100 in the upper drawing of FIG. 3A from above (a top view).

The upper drawing of FIG. 3B illustrates a cross-sectional view of an etching shape obtained by simultaneously performing the treatment step and the etching step of the silicon oxide film 101 when CO gas was added by 3% with respect to the total flow rate of the processing gas (H₂/CF₄/CO) as an embodiment.

The upper drawing of FIG. 3C illustrates a cross-sectional view of an etching shape obtained by simultaneously performing the treatment step and the etching step of the silicon oxide film 101 when CO gas was added by 5% with respect to the total flow rate of the processing gas as an embodiment.

According to this, as illustrated in FIG. 3B, when CO gas was added by 3%, the amount of the tungsten residue 102 re-adhering to the openings of the concave portions formed in the mask 100 and the silicon oxide film 101 was reduced. In addition, as indicated by “E” in FIG. 3C, when CO gas was added by 5%, the amount of the tungsten residue 102 re-adhering to the openings of the concave portions formed in the mask 100 and the silicon oxide film 101 was further reduced. From the above, it was found that necking was suppressed by adding CO gas to the processing gas.

F2 and F3 in the lower parts (left) of FIGS. 3B and 3C are drawings obtained by vertically reducing the upper drawings in FIGS. 3B and 3C, respectively, and G2 and G3 in the lower parts (right) of FIGS. 3B and 3C illustrate views obtained by observing the masks 100 in the upper drawings in FIGS. 3B and 3C from above (top views), respectively. According to this, it can be seen that, compared with that in the comparative example of FIG. 3A (when no CO gas is added to the processing gas), the dimensions of the openings in the masks 100 are larger because the necking is suppressed.

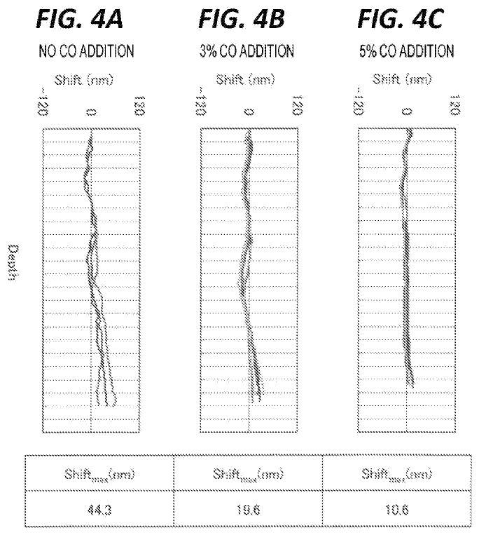

FIG. 4A represents the result obtained by plotting, in the depth direction, the widthwise center position for each of the depths of concave portions obtained by performing the etching step of the silicon oxide film 101 under the same process condition as the comparative example of FIG. 3A, that is, when CO gas was not added to the processing gas. The value “0” on the horizontal axis represents a widthwise center position at the interface between the mask 100 and the silicon oxide film 101, that is, a center line when the shape of a concave portion formed in the silicon oxide film 101 is vertical, and the vertical axis represents a depth starting from the interface between the mask 100 and the silicon oxide film 101 of the concave portion formed in the silicon oxide film 101 by etching. Multiple lines were obtained by calculating the widthwise center positions of concave portions in a plurality of wafers. The fact that the absolute value of a shift amount from a center in the case where the etching shape is vertical increases in the depth direction means that the etching shape becomes a bending shape.

FIGS. 4B and 4C represents the results obtained by plotting, in the depth direction, the widthwise center positions of concave portions obtained under the same process conditions as the comparative examples of FIGS. 3B and 3C, that is, when CO gas was added to the processing gas by 3% and 5%, respectively. Multiple lines were obtained by calculating the widthwise center positions of concave portions in a plurality of wafers.

As a result, when CO gas was not added to the processing gas as represented in FIG. 4A, the maximum value of the shift amount (absolute value) from the center in the case where the etching shape is vertical was 44.3 (nm) due to the occurrence of necking. Meanwhile, when CO gas was added by 3% with respect to the total flow rate of the processing gas as represented in FIG. 4B, since necking was suppressed as illustrated in FIG. 3B, the maximum value of the shift amount (absolute value) from the center in the case where the etching shape is vertical was 19.6 (nm). This is less than half the maximum value of the shift amount (absolute value) when CO gas was not added to the processing gas as represented in FIG. 4A.

When CO gas was added by 5% with respect to the total flow rate of the processing gas as represented in FIG. 4C, since necking was further suppressed as represented in in FIG. 4C, the maximum value of the shift amount (absolute value) in the case where the etching shape is vertical was 10.6 (nm). This is ¼ or less of the maximum value of the shift amount (absolute value) in the case where CO gas was not added to the processing gas as represented in in FIG. 4A.

In the results of FIGS. 3A to 3C and FIGS. 4A to 4C, necking is suppressed and bending shapes are also suppressed by increasing the added amount of CO gas and decreasing the tungsten residue 102. However, it is not always preferred that the necking due to the tungsten residue 102 is small or not. For example, depending on the mask shape before etching and the size of the bottom CD as a target, it may be desirable to control the tungsten residue 102 to set the CD of necking to an appropriate size. In this case, from the results of FIGS. 3A to 3C and FIGS. 4A to 4C, it is possible to control the amount of the tungsten residue 102 and the CD size of necking by adjusting the added amount of CO gas.

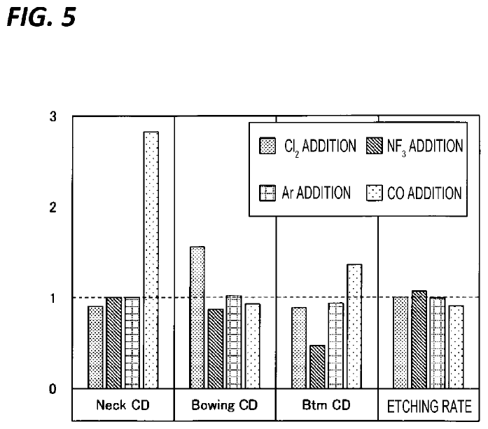

FIG. 5 represents the results of a test in which gases to be added to the processing gas were set to CO gas, Cl₂ gas, NF₃ gas, and Ar gas, respectively. Other process conditions are the same as the process conditions described above.

The horizontal axis of FIG. 5 represents a neck CD, a bowing CD, a bottom CD, and an etching rate when the above four types of gases were added. The value “1” on the vertical axis is a standardized value, and when each gas was added but there is no change from the value of each item when each gas was not added, it is set to “1.”

According to this, when Cl₂ gas, NF₃ gas, and Ar gas were added, the neck CD has a value of about 1 or less than 1. Thus, even if each of these gases was added, necking was not suppressed or got worse. In contrast, when CO gas was added, necking was suppressed about three times compared with when CO gas was not added.

Regarding bowing CD, when Cl₂ gas was added, the verticality of an etching shape was deteriorated. When Ar gas was added, the bowing CD did not change, and when NF₃ gas and CO gas were added, the bowing CD was reduced.

Regarding the bottom CD, the tip tapering-off was improved when CO gas was added, whereas the tip tapering-off got worse when Cl₂ gas, NF₃ gas, and Ar gas were added.

Regarding the etching rate, addition of any of Cl₂ gas, NF₃ gas, Ar gas, and CO gas had almost no effect on the etching rate.

From the above, when CO gas was added to the processing gas, it was possible to suppress necking without affecting the etching rate. Thus, as a ripple effect, the bowing CD and the bottom CD were improved, and etching could be performed in a more vertical shape.

In contrast, even if Cl₂ gas, NF₃ gas, and Ar gas were added, it was impossible to suppress necking. As a result, since the bowing CD was not reduced and the bottom CD was not increased, it was impossible to perform etching in a vertical shape.

[Necking Suppressing Mechanism]

From the above tests, it was found that it is possible to suppress necking by adding CO gas to the processing gas. A necking suppressing mechanism in this case will be described. In the etching step, the silicon oxide film 101 is mainly etched using fluorine gas contained in the processing gas. In this case, when the fluorine gas reacts with the tungsten of the mask 100, highly volatile WF₆ is generated as represented in Equation (1).

W+6F→WF₆↑ (1)

The WF₆ is not only volatilized as it is, but also reacts with Si contained in a reaction product generated when the silicon oxide film 101 is etched. Then, as represented in Equation (2), a reduction reaction of tungsten occurs by Si, and thus tungsten is extracted and SiF₄ having high volatility is generated.

WF₆+Si→W↓+SiF₄↑ (2)

Thus, SiF₄ volatilizes, and tungsten remains. The remaining tungsten re-adheres to the tungsten mask 100 to be deposited thereon, and also adheres to the concave portions formed in the etched silicon oxide film 101 to become tungsten residue 102.

The chemical reactions of Equations (1) and (2) form a loop. Therefore, the chemical reaction represented by Equation (1) and the chemical reaction represented by Equation (2) are repeated in the concave portions formed in the silicon oxide film 101. As a result, due to the re-deposition of the extracted tungsten, the tungsten residue 102 increases, and necking occurs in the openings 103 in the tungsten mask 100. In addition, when the tungsten residue 102 further increases, the openings 103 in the tungsten mask 100 are closed.

Here, when CO gas is added, the tungsten reacts with the CO gas to generate hexacarbonyl tungsten (hereinafter, referred to as “W(CO)₆”) as represented in Equation (3).

W+6CO→W(CO)₆ (3)

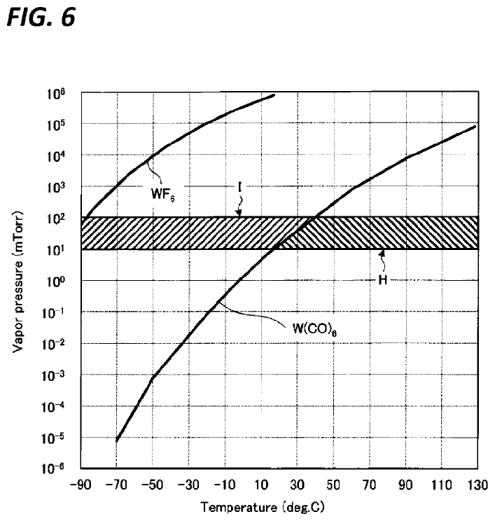

FIG. 6 represents a vapor pressure curve of W(CO)₆. A vapor pressure curve of WF₆ is also represented for reference. When the pressure of the process conditions is set to any value between 10 mT and 100 mT, W(CO)₆ volatilizes at a temperature indicated in the area “H” in FIG. 6, and does not volatilize at a temperature indicated in the area “I.” For example, when the process pressure is 100 mT, W(CO)₆ volatilizes at a normal temperature of 40° C. or higher, and does not volatilize at a temperature lower than 40° C. Therefore, this substrate processing method includes a step of cooling the wafer W to a temperature equal to or lower than a predetermined temperature. The “predetermined temperature” is a temperature determined by a pressure (total pressure) set in the process conditions and the vapor pressure curve, and is a temperature lower than a temperature represented by the vapor pressure curve of W(CO)₆ with respect to the pressure (total pressure) set in the process conditions.

In this manner, a step of treating the wafer W with plasma generated by the processing gas to which CO gas is added is performed under an environment (pressure and temperature) in which W(CO)₆ is capable of being extracted in a solid state. In addition, simultaneously with or after the treatment step, a step of etching the wafer W with plasma generated by a halogen-containing gas is performed.

In the treatment step, the surface of the tungsten mask 100 and the surface of the tungsten residue 102 are modified so as to be turned into W(CO)₆. Thus, even if CO gas is added, the etching of tungsten is not promoted more than necessary, and it is possible to secure the selectivity of the mask 100. Meanwhile, CO reacts with tungsten, but hardly reacts with Si and a silicon oxide film. Therefore, it is possible to suppress necking of the openings in the mask 100 in the state in which the shape of each concave portions formed in the silicon oxide film 101 is kept vertical.

In addition, during the etching performed simultaneously with the treatment, ions in the plasma are made to be incident on the silicon oxide film 101, and the etching is promoted by a mutual reaction of a physical action by ion collision and a chemical action by radicals in the plasma. In Equation (4), the heat input due to ion collision is represented by Qᵢₒₙ.

W(CO)₆+Qᵢₒₙ→W(CO)₆↑ (4)

It is considered that, even when the temperature of the wafer W is controlled to 0° C. or lower, the temperature of the surface of the wafer W locally and instantaneously increases due to the heat input Qᵢₒₙ due to ion collision. Accordingly, as represented in Equation (4), the temperature of W(CO)₆ deposited as a solid locally and instantaneously becomes higher than a temperature represented by the vapor pressure curve with respect to the pressure set in the process conditions due to the heat input Qᵢₒₙ, and thus the solid W(CO)₆ is turned into gas (W(CO)₆↑) and volatilizes. Meanwhile, since the average temperature of the wafer W remains low, the solid W(CO)₆ is not continuously and spontaneously turned into gas (W(CO)₆↑), and volatilizes only when ion collision occurs.

The temperature of the wafer is adjusted since heat is transferred from the electrostatic chuck cooled by circulating a coolant cooled to a predetermined temperature to the wafer through a heat transfer gas. However, due to the heat input Qᵢₒₙ due to continuous ion collision, the average temperature of the entire wafer may be higher than the adjusted temperature. Therefore, when it is possible to measure the actual temperature of the wafer during the etching processing, or when it is possible to estimate the temperature difference between the adjusted temperature of the wafer and the actual surface temperature of the wafer from the process conditions, it is desirable to adjust the temperature of the wafer in a temperature range lower than the temperature represented by the vapor pressure curve of W(CO)₆.

As described above, according to the substrate processing method according to an embodiment, by controlling the temperature of the wafer W to a predetermined temperature and adding CO gas to the processing gas, the W(CO)₆ is generated in the solid state and the surfaces of the mask and the tungsten residue 102 are modified so as to be turned into the W(CO)₆. In this state, W(CO)₆ is locally turned into a volatile gas and volatilizes due to the heat input Qᵢₒₙ when ions collide with the tungsten residue 102. This makes it possible to suppress necking by removing the tungsten residue 102 from the openings of the concave portions formed in the mask 100 and the silicon oxide film 101 while securing the selectivity of the mask 100.

That is, the tungsten of the mask 100 follows one of the route in which the reactions of Equations (1) and (2) are repeated and the route in which carbonylation occurs by the reaction of Equation (3). In this case, when the partial pressure of CO gas with respect to the total flow rate of the processing gas is high, the probability of carbonylation of tungsten increases, and the amount of tungsten remaining on the mask 102 as the residue 102 decreases. It is believed that necking is suppressed in this way.

A method of processing a wafer W including a mask 100 formed of tungsten and having openings 103 and a silicon oxide film 101 formed below the mask 100 has been described. This method includes a step of cooling the wafer W provided in the processing container 10 to a predetermined temperature or lower. In addition, the method includes a step of treating the wafer W with plasma generated by CO gas, and a step of etching the wafer W with plasma generated by a halogen-containing gas.

Therefore, W(CO)₆ is generated in a solid state by the chemical reactions represented in Equations (3) and (4) without passing through the chemical reaction paths of Si reduction represented in Equations (1) and (2), and some of the W(CO)₆ volatilizes. This makes it possible to suppress necking by volatilizing the tungsten residue 102, which has adhered to the mask 100, while ensuring the selectivity of the mask 100.

[Substrate Processing]

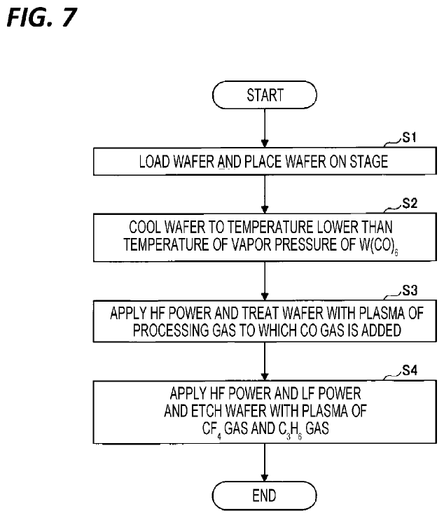

Finally, a substrate processing method according to an embodiment, controlled by the controller 40, will be described with reference to FIG. 7. FIG. 7 is a flowchart illustrating an exemplary substrate processing method according to an embodiment.

When the present processing is started, the controller 40 executes a step of supplying a wafer W by loading the wafer W into the processing chamber 10 and placing the wafer W on the stage 11 (step S1). Next, the controller 40 executes a step of cooling the wafer W to a temperature lower than the temperature of the vapor pressure of W(CO)₆ at a predetermined pressure set in the process conditions (step S2). The predetermined pressure set in the process conditions is 25 mT or lower.

Next, the controller 40 executes a step of treating the wafer W with plasma generated by the processing gas to which CO gas is added (step S3). Next, the controller 40 executes a step of etching the wafer W by the plasma generated by CF₄ gas (step S4), and ends the present processing.

According to the substrate processing method according to the embodiment described above, at least one surface of tungsten included in a reaction product generated in the step of etching the wafer W or tungsten included in the mask 100 is carbonylated to W(CO)₆. Then, W(CO)₆ is locally volatilized by the heat input from ions in a location where ions collide. This makes it possible to suppress necking by removing the tungsten residue 102 on the mask.

In the etching step, the silicon oxide film 101 is etched through the openings 103 in the mask 100. Therefore, it is possible to vertically form the etching shape of the silicon oxide film 101 by suppressing necking and widening the openings 103 in the mask 100 by removing the tungsten residue 102. Thus, it is possible to suppress bowing, bending, and tip tapering-off. Meanwhile, the addition of CO gas does not affect the etching rate, and is able to maintain a high etching rate in a low-temperature environment.

### Modification

In the order of performing the treatment step and the etching step, the etching step may be performed after the treatment step is performed, or may be performed simultaneously with the treatment step. When the etching step and the treatment step are performed simultaneously, a gas having a carbonyl bond and a halogen is used as the processing gas. In addition, the treatment step and the etching step may be alternately performed a predetermined number of times.

In the above-described embodiment, the mask 100 is formed of tungsten. However, the material forming the mask 100 is not limited to tungsten, and may be any transition metal. The transition metal may be tungsten, nickel, or chromium.

In addition, W(CO)₆ is an example of a material obtained by carbonylating a carbon monoxide complex of the transition metal, and is not limited thereto. The material obtained by carbonylating the carbon monoxide complex of the transition metal may be a material obtained by carbonylating a carbon monoxide complex of nickel or chromium.

In addition, in the above-described embodiment, a wafer W in which a tungsten mask 100 is formed immediately above a silicon oxide film 101, which is an etching target film, is used, but the present disclosure is not limited thereto. The same etching may be performed as long as an intermediate layer of, for example, a polysilicon film or an amorphous silicon film is provided between the etching target film and the mask, and the intermediate layer also has an opening like the mask. The intermediate layer is preferably a film having a selectivity with respect to the etching target film, such as, for example, a silicon nitride film or an organic film, in addition to the polysilicon film.

In the above embodiment, the silicon oxide film 101 is used as the etching target film. However, the etching target film is not limited thereto, and it is possible to use any film as the etching target film as long as the film contains silicon. As an example of the silicon-containing film, a silicon insulating film such as, for example, a silicon oxide film, a silicon nitride film, a silicon carbide film, or a silicon nitride carbide film, may be used. In addition, a silicon film such as, for example, a polysilicon film, a silicon single crystal film, or an amorphous silicon film, may be used. A stacked film of a silicon oxide film and a silicon nitride film, a stacked film of a silicon oxide film and a polysilicon film, a stacked film of two types of polysilicon films having different doping amounts, or a stacked film of other two or more films described above. Since the etching target film is a silicon-containing film, a reaction product containing silicon is generated during the etching step.

In addition, the processing gas to which CO gas is added in the treatment step is an example of a gas having a carbonyl bond (CO bond), but is not limited thereto. The gas having a carbonyl bond may be at least one of CO, CO₂, COS, COF, COF₂, acetone (CH₃COCH₃), methane ethane ketone (CH₃COC₂H₅), or acetic acid.

When a gas having a carbonyl bond, other than CO gas, is used as the processing gas in the treatment step, a bond other than the carbonyl group contained in the processing gas is added to the reaction represented in Equation (3), and the vapor pressure curve of W(CO)₆ may shift. In particular, when the vapor pressure curve shifts to the low vapor pressure side (the right side in FIG. 6), the temperature at which the processing gas modifies the surface of tungsten so as not to volatilize shifts to the high temperature side. Therefore, if it is possible to perform treatment such that the processing gas does not volatilize with respect to the mask 100 and the residue 102, the “predetermined temperature” is not necessarily a temperature lower than the temperature represented by the vapor pressure curve of W(CO)₆ with respect to the pressure set in the process conditions.

In addition, by side effects by the surface states of the mask 100 and the residue 102, a pre-processing condition before performing the treatment step, or a gas added to the processing gas in the treatment step other than a gas having a carbonyl bond, the vapor pressure curve of W(CO)₆ may shift. Therefore, if it is possible to perform treatment such that the processing gas does not volatilize with respect to the mask 100 and the residue 102 by the effects by these conditions, the “predetermined temperature” is not necessarily a temperature lower than the temperature represented by the vapor pressure curve of W(CO)₆ with respect to the pressure set in the process conditions.

In addition, the CF₄ gas supplied in the etching step is an example of a halogen-containing gas, and is not limited thereto. When etching the silicon insulating film, the halogen-containing gas only needs to contain fluorine. However, as the halogen-containing gas, it is preferable that a halogen-containing gas be contained in a fluorine-containing gas. This makes it possible to improve the etching rate. The fluorine-containing gas may be at least one of CF₄, CH₂F₂, NF₃, CHF₃, C₄F₈, C₄F₆, and C₃F₈. The hydrogen-containing gas may be at least one of C₃H₆, H₂, HBr, CH₂F₂, CH₄, and CHF₃. When etching the silicon film, the halogen-containing gas only needs to contain chlorine or bromine, and may be at least one of, for example, Cl₂, HCl, and HBr.

In the etching step, LF power for ion attraction may be applied to the stage 11 on which a wafer W is placed. This makes it possible to control the heat input of ions during the etching step, and to promote Equation (4) so as to volatilize the tungsten residue as tungsten carbonyl. Thus, it is possible to remove necking. Meanwhile, it is preferable to apply LF power in the etching step, but it is not necessary to apply LF power in the treatment step.

The substrate processing apparatus of the present disclosure is applicable to any of an atomic layer deposition (ALD) type apparatus, a capacitively coupled plasma (CCP) type apparatus, an inductively coupled plasma (ICP) type apparatus, a radial line slot antenna type apparatus, an electron cyclotron resonance plasma (ECR) type apparatus, and a helicon wave plasma (HWP) type apparatus. In addition, a plasma processing apparatus has been described as an example a substrate processing apparatus. However, the substrate processing apparatus is not limited to the plasma processing apparatus, and may be any apparatus as long as the substrate processing apparatus performs a predetermined processing (e.g., a film forming processing or an etching processing) on a substrate. For example, the substrate processing apparatus may be a CVD device.

The present disclosure provides a substrate processing method and a substrate processing apparatus capable of suppressing necking based on a residue of a transition metal mask.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
etching a target film formed on a substrate through an opening of a mask formed on the target film with plasma generated from a mixed gas obtained by adding a gas having a carbonyl bond to a halogen-containing gas, the target film containing silicon, and the mask being formed of a transition metal.

2. The substrate processing method according to claim 1, further comprising:
cooling the substrate to a predetermined temperature or lower before the etching.

3. The substrate processing method according to claim 2, wherein the predetermined temperature is lower than a temperature represented by a vapor pressure curve of a carbon monoxide complex of the transition metal with respect to a set pressure value in the etching.

4. The substrate processing method according to claim 1, wherein the gas having a carbonyl bond is at least one of CO, CO₂, COS, COF, COF₂, acetone (CH₃COCH₃), methane ethane ketone (CH₃COC₂H₅), or acetic acid.

5. The substrate processing method according to claim 1, wherein the transition metal is tungsten, nickel, or chromium.

6. The substrate processing method according to claim 1, wherein the halogen-containing gas contains hydrogen.

7. The method according to claim 1, wherein an adhering amount of a reaction product containing the transition metal and adhering to a side wall of the opening in the mask is controlled by increasing or decreasing an addition ratio of the gas having a carbonyl bond with respect to a total flow rate of the mixed gas.

8. A substrate processing method comprising:
treating a target film formed on a substrate with plasma generated by a gas having a carbonyl bond, wherein the target film contains silicon, and a mask made of a transition metal and having an opening is formed on the target film; and
etching the target film formed on the substrate with plasma generated by a halogen-containing gas.

9. The substrate processing method according to claim 8, wherein the treating and the etching are performed in a same step.

10. The method according to claim 8, wherein the treating and the etching are performed alternately a predetermined number of times.

11. The substrate processing method according to claim 8, further comprising:
cooling the substrate to a predetermined temperature or lower before the treating and the etching.

12. The substrate processing method according to claim 11, wherein the predetermined temperature is lower than a temperature represented by a vapor pressure curve of a carbon monoxide complex of the transition metal with respect to a set pressure value in the treating.

13. The substrate processing method according to claim 8, wherein, in the etching, the target film is etched through the opening of the mask.

14. The substrate processing method according to claim 8, wherein, in the treating, a surface of at least one of the transition metal included in a reaction product generated in the etching and the transition metal included in the mask is carbonylated into a carbon monoxide complex of the transition metal.

15. The substrate processing method according to claim 8, wherein the gas having a carbonyl bond is at least one of CO, CO₂, COS, COF, COF₂, acetone (CH₃COCH₃), methane ethane ketone (CH₃COC₂H₅), or acetic acid.

16. The substrate processing method according to claim 8, wherein the transition metal is tungsten, nickel, or chromium.

17. The substrate processing method according to claim 8, wherein, in the treating, a radio-frequency power for plasma generation is applied to a stage on which the substrate is disposed, and
in the etching, a radio-frequency power for plasma generation and a radio-frequency power for ion attraction are applied to the stage.

18. The substrate processing method according to claim 8, wherein the halogen-containing gas contains hydrogen.

19. The substrate processing method according to claim 8, wherein, during the etching, a reaction product containing silicon is generated.

20. A substrate processing apparatus comprising:
a controller that controls a processing of a substrate including a mask formed of a transition metal and having an opening, and a target film to be etched containing silicon formed below the mask,
wherein the controller is configured to control a process including:
treating the substrate with plasma generated by a gas having a carbonyl bond; and
etching the substrate with plasma generated by a halogen-containing gas.
